(19) United States
(12) Patent Application Publication
(10) Pub. No.: US 2011/0272001 A1
(43) Pub. Date: Nov. 10, 2011

(54) PHOTOVOLTAIC PANEL ASSEMBLY WITH HEAT DISSIPATION FUNCTION

(75) Inventors: Szu-Han LI, Taoyuan County (TW); Yi-Ling Chen, Taichung City (TW); Ching-Yee Chak, Hong Kong (HK); Wing-Yan Lai, Hong Kong (HK); Hung-Ming Tseng, Taipei City (TW); Chi-Lung Chien, Hong Kong (HK)

(73) Assignee: Du Pont Apollo Limited, Hong Kong (HK)

(21) Appl. No.: 13/099,381

(22) Filed: May 3, 2011

Related U.S. Application Data
(60) Provisional application No. 61/330,896, filed on May 4, 2010.

(51) Int. Cl. H01L 31/052

(52) U.S. Cl. 136/246

(57) ABSTRACT

A photovoltaic panel assembly includes a photovoltaic panel of two opposite surfaces. A photovoltaic array is disposed on one of the two opposite surfaces. The heat sink is disposed over the other of the two opposite surfaces, wherein the heat sink comprises a wavy cross-section.

### RELATED APPLICATIONS

This application claims priority to U.S. Provisional Application Ser. No. 61/330,896, filed May 4, 2010, which is herein incorporated by reference.

### BACKGROUND

1. Field of Invention

The present invention relates to a photovoltaic panel assembly with a heat-dissipating function.

2. Description of Related Art

Photovoltaic sun concentrators used with photovoltaic (PV) solar cells provide a way of making solar electric energy cost competitive compared to conventional electric generation technologies such as fossil fuels. The concentration of the sun's energy creates heat and thus it is necessary to cool the PV solar cells that are exposed to concentrated solar radiation. When PV cells are operated under normal solar radiation, they may reach temperatures of up to 70-90° C. and several hot spots over one hundred degrees. When concentrators are used, these devices may reach temperatures of several hundred degrees if cooling is not provided. Such high temperatures lead to several negative effects. For example, cell efficiency decreases proportionally to temperature and electrical power output is reduced. In addition, many materials used in PV cells have an operating range that typically does not exceed +150 degrees Celsius.

For the forgoing reasons, there is a need for a solar panel assembly to employ a better heat dissipation solution.

### SUMMARY

It is therefore an objective of the present invention to provide a photovoltaic panel assembly with a heat-dissipating function.

In accordance with the foregoing and other objectives of the present invention, a photovoltaic panel assembly includes a photovoltaic panel of two opposite surfaces. A photovoltaic array is disposed on one of the two opposite surfaces. The heat sink is disposed over the other of the two opposite surfaces, wherein the heat sink comprises a wavy cross-section.

According to an embodiment disclosed herein, the photovoltaic panel assembly further includes a thermal pad disposed between the heat sink and the other of the two opposite surfaces.

According to another embodiment disclosed herein, the thermal pad includes a silicone layer.

According to another embodiment disclosed herein, the thermal pad includes an intermediate thermal layer sandwiched by two silicone layers, wherein the intermediate thermal layer has a higher thermal conductivity than the two silicone layers do.

According to another embodiment disclosed herein, the intermediate thermal layer includes aluminum, cooper, sliver or diamond powders.

According to another embodiment disclosed herein, the heat sink is in contact with the other of the two opposite surfaces to define a plurality of separate hollow channels.

According to another embodiment disclosed herein, the plurality of separate hollow channels has two openings at two opposite ends.

According to another embodiment disclosed herein, one of the two openings extends along a crest of the wavy cross-section.

According to another embodiment disclosed herein, the photovoltaic panel assembly further includes a fan disposed at one of the two openings.

According to another embodiment disclosed herein, the photovoltaic panel assembly further includes a fan disposed at a lower one of the two openings.

According to another embodiment disclosed herein, the photovoltaic panel assembly further includes a plurality of fans disposed at both the two openings.

According to another embodiment disclosed herein, the photovoltaic panel assembly further includes a fan disposed on the heat sink.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a perspective view of a photovoltaic panel assembly according to one preferred embodiment of this invention;

FIG. 2 illustrates a perspective view of a photovoltaic panel assembly according to another preferred embodiment of this invention; and

FIG. 3 illustrates a cross-sectional view of a photovoltaic panel assembly according to still another preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

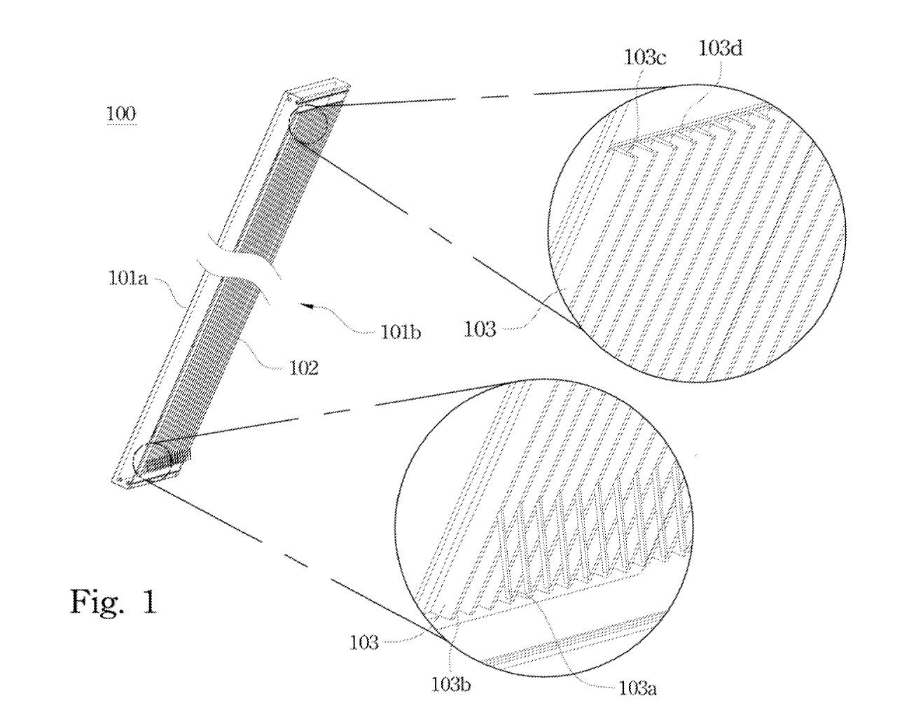

FIG. 1 illustrates a perspective view of a photovoltaic panel assembly according to one preferred embodiment of this invention. The photovoltaic panel assembly 100 has two opposite sides (101a and 101b). The light-receiving side 101a is equipped with a photovoltaic array for transforming the incident light into electrical energy. The back side 101b is equipped with a heat sink 102 of a wavy cross-section 103 (see an upper enlarged view) to heat dissipate the photovoltaic panel assembly 100. A plurality of troughs 103d of the heat sink 102 are in contact with the back side 101b so as to define separate hollow channels between the heat sink 102 and back side 101b, whereby allowing airflow to pass therethrough. Each hollow channel has two openings (103c, 103b) at opposite ends, which serve as air inlets or air outlets. The opening 103b is formed along a crest of the heat sink 102 by removing a crest top 103a from its original place. The same design of the opening 103b may also be applied to the opening 103c. By positioning an edge of the photovoltaic panel assembly 100 at a lower altitude and an opposite edge of the photovoltaic panel assembly 100 at a higher altitude, the heated air within the hollow channel is moved upward and the fresh air with a lower temperature is thus introduced through a lower opening, e.g. the opening 103b. The heat convection within the hollow channel is hence achieved and heat dissipation would be enhanced.

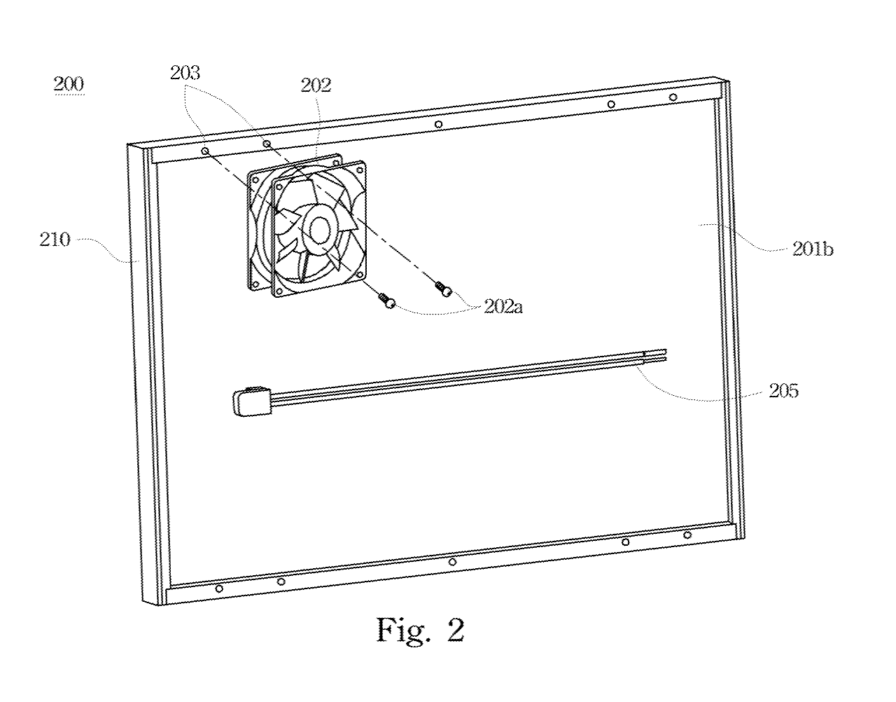

FIG. 2 illustrates a perspective view of a photovoltaic panel assembly according to another preferred embodiment of this invention. Bedsides the passive heat dissipation illustrated in FIG. 1, an active heat dissipation way may also be used on a back side 201b of a photovoltaic panel 200. In this embodiment, one or more fans 202 are installed on the back side 201b of a photovoltaic panel 200. Bolts 202a are used to insert through holes of the fan 202 and screwed into threaded holes 203 in order to fasten the fan 202 onto the frame 210 of the photovoltaic panel 200. The fan 201 can be driven by the power generated by the photovoltaic panel assembly 200 itself, e.g. electrically connected with a pair of power cables 205. That is, the photovoltaic panel assembly 200 not only outputs power for external use but also supplies power for its active heat dissipation.

Referring to both FIG. 1 and FIG. 2, the fan 202 may be installed on the heat sink 102 to enhance heat dissipation. For example, the fan 202 can be installed at the lower opening 103b or the upper opening 103c to force the heat convection, thereby improving the heat dissipation. The fan 202 can be installed at the lower opening 103b to introduce the fresh air into the hollow channel, or the fan 202 can be installed at the lower opening 103c to exhaust the heated air out of the hollow channel. Besides, two fans can also be respectively installed at the lower and upper openings (103b, 103c) of the hollow channel.

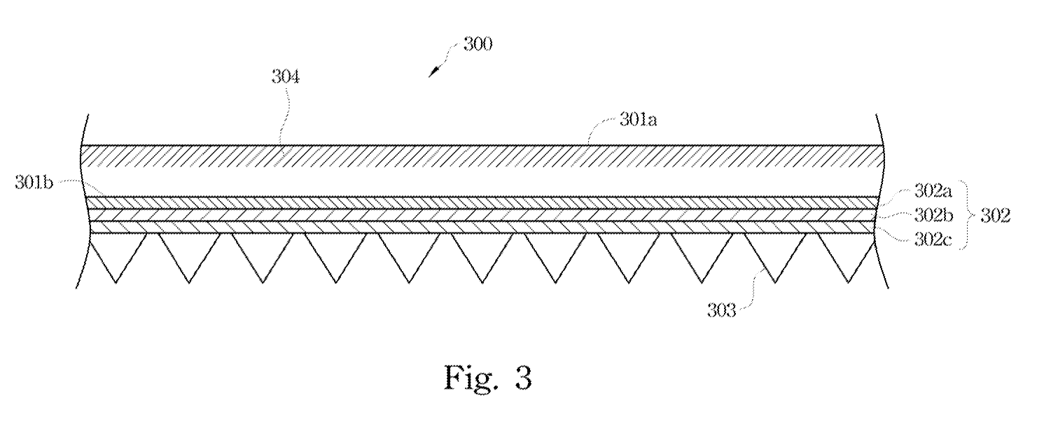

FIG. 3 illustrates a cross-sectional view of a photovoltaic panel assembly according to still another preferred embodiment of this invention. The heat-dissipating mechanism can be further enhanced by adding a better thermally-conductive interface. In particular, a thermal pad 302 is added between the photovoltaic panel and the heat sink 303 to form a better thermally-conductive interface, i.e. between a back side 301b of the photovoltaic panel and the heat sink 303. The thermal pad 302 includes an intermediate thermal layer 302b sandwiched by two silicone layers (302a, 302c). The intermediate thermal layer 302b has a higher thermal conductivity than the two silicone layers (302a, 302c) do. The intermediate thermal layer 302b can be aluminum, cooper, sliver, diamond powders or other high thermally-conductive materials. In an alternate embodiment, the thermal pad may be a single silicone layer, e.g. a single silicone layer 302a, without the thermal layer 3026. The thermal pad 302 is to accelerate heat-transfer between the photovoltaic panel and the heat sink 303. Since the photovoltaic panel assembly 300 is operated at a lower temperature, a photovoltaic array 304 on a light-receiving side 301a of the photovoltaic panel can be operated more efficiently, i.e. transforming the receiving light into electrical energy efficiently.

According to the above-discussed embodiment, the present invention provides a photovoltaic panel assembly with an improved heat-dissipating design, e.g. passive or active heat sink, to lower its operation temperature, thereby improving its operation efficiency, i.e. transforming the receiving light into electrical energy more efficiently.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic panel assembly comprising:
a photovoltaic panel comprising two opposite surfaces;
a photovoltaic array disposed on one of the two opposite surfaces; and
a heat sink disposed over the other of the two opposite surfaces, wherein the heat sink comprises a wavy cross-section.

2. The photovoltaic panel assembly of claim 1, further comprising a thermal pad disposed between the heat sink and the other of the two opposite surfaces.

3. The photovoltaic panel assembly of claim 2, wherein the thermal pad comprises a silicone layer.

4. The photovoltaic panel assembly of claim 2, wherein the thermal pad comprises an intermediate thermal layer sandwiched by two silicone layers, wherein the intermediate thermal layer has a higher thermal conductivity than the two silicone layers do.

5. The photovoltaic panel assembly of claim 4, wherein the intermediate thermal layer comprises aluminum, cooper, sliver or diamond powders.

6. The photovoltaic panel assembly of claim 1, wherein the heat sink is in contact with the other of the two opposite surfaces to define a plurality of separate hollow channels.

7. The photovoltaic panel assembly of claim 6, wherein the plurality of separate hollow channels has two openings at two opposite ends.

8. The photovoltaic panel assembly of claim 7, wherein one of the two openings extends along a crest of the wavy cross-section.

9. The photovoltaic panel assembly of claim 7, further comprising a fan disposed at one of the two openings.

10. The photovoltaic panel assembly of claim 7, further comprising a fan disposed at a lower one of the two openings.

11. The photovoltaic panel assembly of claim 7, further comprising a plurality of fans disposed at both the two openings.

12. The photovoltaic panel assembly of claim 1, further comprising a fan disposed on the heat sink.
